(19) United States
(12) Patent Application Publication
(10) Pub. No.: US 2026/0324403 A1
(43) Pub. Date: Oct. 15, 2026

(54) BONDING INTERFACE BETWEEN A DIE AND CARRIER WAFER

(71) Applicant: Intel Corporation, Santa Clara, CA (US)

(72) Inventors: Gwang Soo Kim, Portland, OR (US); Julia Chiu, Portland, OR (US); Shawna M. Liff, Scottsdale, AZ (US); Amy Roskowski, Portland, OR (US); Karson Knutson, Beaverton, OR (US); Jordan Crist, Newberg, OR (US); Patrick Kain, Portland, OR (US); Bhaskar Jyoti Krishnatreya, Beaverton, OR (US)

(73) Assignee: Intel Corporation, Santa Clara, CA (US)

(21) Appl. No.: 19/176,653

(22) Filed: Apr. 11, 2025

(51) Int. Cl. H01L 23/00; H01L 23/522; H01L 23/528

(52) U.S. Cl. CPC H10W 20/435; H10W 20/42; H10W 72/07331; H10W 72/322; H10W 72/352; H10W 90/734

(57) ABSTRACT

Bonding interfaces between a die and a carrier wafer are described herein. Using a bonding layer between wafers that includes metal, a doped dielectric material, and/or a semiconductor material may reduce damage from processes such as dicing. In one example, dopants are introduced into a dielectric material before bonding. In another example, the bonding layer includes a semiconductor material. In one example, a conductive material including a metal is used as a bonding interface between wafers. In some examples, the metallic bonding material may be patterned. In some examples, a conductive material including metal may replace a dielectric material as a bonding material. In other examples, the bonding interface may include a layer of conductive material and a layer of a dielectric material or a semiconductor material.

### BACKGROUND

Electronic circuits when commonly fabricated on a wafer of semiconductor material, such as silicon, are called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system, or servers, such as mainframes.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A illustrates cross-sectional side views of wafers at various points in a wafer-to-wafer bonding process, according to embodiments of the present disclosure.

FIG. 1B illustrates cross-sectional side views of wafers at various points during an example of die processing and singulation process, according to embodiments of the present disclosure.

FIG. 2 illustrates a cross-sectional side view of an example die including a portion of a carrier wafer and a bonding interface, according to embodiments of the present disclosure.

FIG. 3 is a flow diagram of an example method for fabricating a microelectronic component with a bonding interface between a die and carrier wafer, in accordance with some embodiments.

FIG. 4 provides cross-sectional side views at various stages in the fabrication of an example microelectronic component according to the method of FIG. 3, in accordance with some embodiments.

FIG. 5 is a flow diagram of an example method for fabricating a microelectronic component with a bonding interface between a die and carrier wafer, in accordance with some embodiments.

FIG. 6 provides cross-sectional side views at various stages in the fabrication of an example microelectronic component according to the method of FIG. 5, in accordance with some embodiments.

FIG. 7 is a flow diagram of an example method for fabricating a microelectronic component with a bonding interface between a die and carrier wafer, in accordance with some embodiments.

FIG. 8 provides cross-sectional side views at various stages in the fabrication of an example microelectronic component according to the method of FIG. 7, in accordance with some embodiments.

FIG. 9 is a flow diagram of an example method for fabricating a microelectronic component with a bonding interface between a die and carrier wafer, in accordance with some embodiments.

FIG. 10 provides cross-sectional side views at various stages in the fabrication of an example microelectronic component according to the method of FIG. 9, in accordance with some embodiments.

FIG. 11 is a flow diagram of an example method for fabricating a microelectronic component with a bonding interface between a die and carrier wafer, in accordance with some embodiments.

FIGS. 12A-12C, 13A-13B, and 14A-14B provide cross-sectional side views at various stages in the fabrication of an example microelectronic component according to the method of FIG. 11, in accordance with some embodiments.

FIG. 15 is a top view of a wafer and dies that may include any of the wafers and dies disclosed herein, in accordance with any of the embodiments disclosed herein.

FIG. 16 is a side, cross-sectional view of an IC package that may include any microelectronic component disclosed herein, in accordance with various embodiments.

FIG. 17 is a side, cross-sectional view of an IC device assembly that may include an assembly or any of the microelectronic components disclosed herein, in accordance with any of the embodiments disclosed herein.

FIG. 18 is a block diagram of an example electrical device that may include an assembly or any of the microelectronic components disclosed herein, in accordance with any of the embodiments disclosed herein.

### DETAILED DESCRIPTION

Disclosed herein are microelectronic components including a bonding interface between a die and carrier wafer that may reduce damage from the dicing process. The systems, methods, and devices of this disclosure each have several innovative aspects, no single one of which is solely responsible for all desirable attributes disclosed herein. Details of one or more implementations of the subject matter described in this specification are set forth in the description below and the accompanying drawings.

In fabricating microelectronic components, a carrier wafer may sometimes be used to provide support and/or enable backside processing of a wafer that includes devices. For example, in order to implement backside power delivery, a wafer including devices may be flipped over and bonded with a carrier wafer to enable backside processing, such as thinning/removal of the substrate to enable access to the devices, and providing backside metal layers for power delivery. The carrier wafer can provide structural support that may otherwise be lacking due to the removal of some or all of the substrate over which the devices were formed. In some examples, the entire wafer stack including the carrier wafer and the device wafer is diced, resulting in dies that include a portion of the carrier wafer below the device region.

Accordingly, a carrier wafer can be useful for providing structure and the ability to perform backside processing of a device wafer, and a portion of the carrier wafer may remain in the resulting singulated components. Wafers may be stacked and bonded with one another using a wafer-to-wafer bonding technique, which may also be referred to as direct bonding or fusion bonding. Typically, fusion bonding involves deposition of a dielectric film on one of the wafers, which is used as a bonding layer or adhesion layer between the wafers. The wafer stack may then be heated to an elevated temperature (e.g., with an annealing process) to bond the wafers with one another using the dielectric material as a bonding layer. However, dielectric films used as bonding layers can reduce heat and charge transfer, leading to thermal damage and plasma charging effects during die prep processes. For example, as a result of a singulation process using a laser, the dielectric bonding layer may absorb less of the laser light than the wafer, resulting in hot spots at the bonding interface, which can lead to cracks and delamination.

In contrast, using a bonding layer between wafers that includes metal, a doped dielectric material, and/or a semiconductor material may reduce damage from the dicing process. In one example, dopants are introduced into a dielectric material before bonding. In another example, the bonding layer includes a semiconductor material. In one example, a conductive material including a metal is used as a bonding interface between wafers. In some examples, the metallic bonding material may be patterned (e.g., the bonding layer may include metal only in scribe regions or only in expected hot spot regions, such as below device regions). In some examples, the material including metal may replace a dielectric material as a bonding material. In other examples, the bonding interface may include a layer of material including a metal and a layer of a dielectric material or semiconductor material.

Microelectronic components including a bonding interface between a die and carrier wafer that may reduce damage from the dicing process as described herein may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials, and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of an a bonding interface between a die and carrier wafer that may reduce damage from the dicing process as described herein.

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

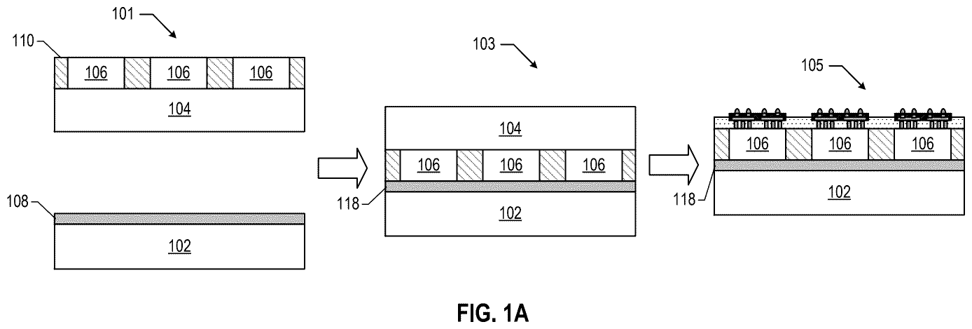

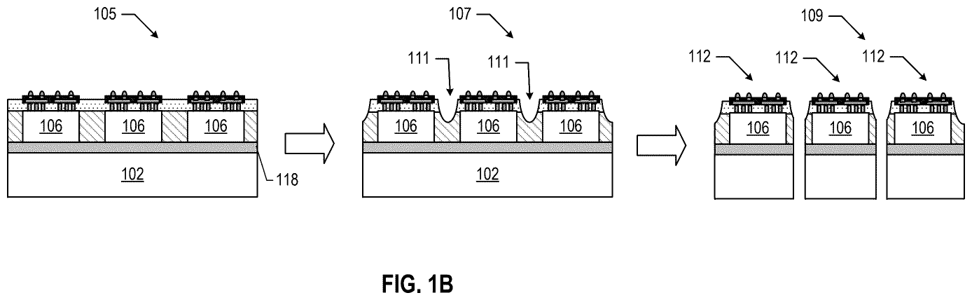

FIG. 1A illustrates cross-sectional side views of wafers at various points during an example of a wafer-to-wafer bonding process. The microelectronic assembly 101 includes a first wafer 102 and a second wafer 104. The first wafer 102 may be a carrier wafer. A carrier wafer is a wafer that provides a structural support, either temporarily or permanently, to another structure, such as the wafer 104. In one example, a carrier wafer may be a non-functional wafer that lacks transistors that are capable of being powered on and processing signals (e.g., the carrier wafer lacks transistors, or transistors present on the carrier wafer are not coupled with power or signal interconnects). The wafer 102 may include any suitable materials that are structurally stiff enough to provide support to another structure. In some examples, the wafer 102 may include silicon, glass, and/or any other suitable material. The wafer 102 may have a round (e.g., circular) shape and have any thickness sufficient for providing mechanical support.

The wafer 104 is an example of a wafer that includes devices, and may thus be referred to as a device wafer or a base wafer. The wafer 104 may have a round (e.g., circular) shape, and may represent a wafer of a semiconductor material that has undergone frontend and backend processing. Thus, the wafer 104 may include frontend of line (FEOL) layers (e.g., a device region) and backend of line (BEOL) layers (e.g., interconnect layers of a metallization stack). In some examples, the bulk semiconductor material in or over which devices are formed may have been thinned and/or removed. The wafer 104 may include a plurality of dies 106 (e.g., individual die regions), which may be singulated with a subsequent dicing process along scribe regions 110 (also known as a kerf, frame, or scribe lines).

In the example illustrated in FIG. 1A, a layer of a bonding material 108 is provided over the wafer 102 to enable wafer-to-wafer fusion bonding. In other examples, the bonding material 108 may be provided over the wafer 104 instead or, or in addition to, over the wafer 102. The microelectronic assembly 103 illustrates an example of an assembly after the wafer-to-wafer bonding process. In the example illustrated in FIG. 1A, the wafer 104 has been flipped over and bonded with the wafer 102 via the bonding material 108 to form a wafer stack that includes the wafer 102, the wafer 104, and a bonding interface 118 between the wafer 102 and the wafer 104. The bonding interface 118 may also be referred to as a bonding layer, an interface layer, or an adhesion layer. Any suitable bonding technique may be used, such as heating the assembly 103 and/or applying pressure to the assembly 103. FIG. 1A illustrate an example of a front-to-front bonding arrangement in which the front side of the wafer 104 is bonded with the front side of the wafer 102, where the front side of a wafer is the side of the wafer on/over which devices are formed. In other examples, the wafer-to-wafer bonding process may involve front-to-back bonding (e.g., bonding a front side of one wafer with a back side of another wafer) or back-to-back bonding (e.g., bonding a back side of one wafer with a back side of another wafer), where the back side of a wafer is the side of the wafer opposite the front side. Although FIG. 1A depicts an example assembly 103 in which two wafers 102, 104 are bonded with one another, in other examples, as assembly may include more than two wafers stacked over one another and bonded.

In the example illustrated in FIG. 1A, after performing wafer-to-wafer bonding, the substrate over which the devices were formed may be thinned or removed (e.g., with an etching/polishing process), and interconnect layers may be provided over the back side of the wafer 104, as shown in the assembly 105.

FIG. 1B illustrates cross-sectional side views of wafers at various points during an example of die processing and singulation (also known as die prep). Die singulation may involve any suitable process for separating dies from one another, and may involve a laser process (e.g., laser ablation), a mechanical process (e.g., sawing with a rotating circular blade), and/or a plasma process. In the example illustrated in FIG. 1B, the singulation process may first involve laser ablation as shown in the assembly 107. For example, the assembly 107 includes grooves 111 in the scribe regions 110 between adjacent dies 106. Forming grooves 111 may involve removing metal layers to enable a subsequent dicing process, such as a saw process, to singulate the stack. In other examples, the grooves 111 may not be formed prior to singulation. The assembly 109 illustrates an example after the wafer stack has been singulated into individual dies 112.

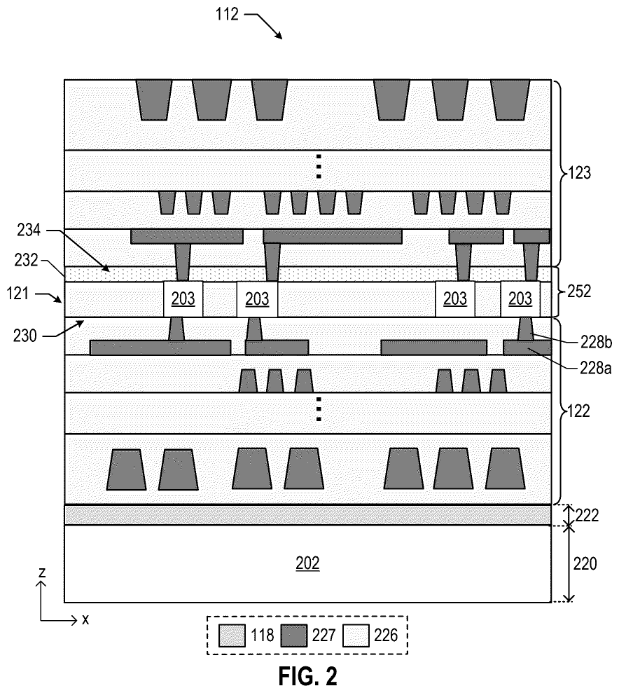

FIG. 2 illustrates a cross-sectional side view of the example die 112 including a portion of a carrier wafer and a bonding interface. The die 112 include FEOL layers 252 and BEOL layers, which include metal layers 122, 123. The FEOL layers 252 include a device region 121, and may also include a substrate 232 over which the device region 121 is disposed. The device region 121 includes devices (of which devices 203 are shown). The substrate 232 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In other examples, the substrate 232 may have been removed from the back side of the wafer (e.g., after bonding with the carrier wafer 102).

According to examples, the devices 203 may include transistors of any architecture, such as any non-planar or planar architecture. Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surface. A confinement surface refers to a particular orientation of the channel surface that is confined by the gate field. Devices in the device region 121 may be electrically isolated from one another by any suitable insulator material or dielectric material 226.

The metal layers 122, 123, which may also be referred to as interconnect layers, may include a plurality of conductive interconnects 227 electrically and conductively coupled to (e.g., in conductive contact with at least portions of) one or more of the plurality of devices 203 of the FEOL layers 252. Various metal layers 122, 123 may be metal layers of a metallization stack. In the example illustrated in FIG. 2, the metal layers 122 are disposed over a side 230 of the device region 121 (e.g., over a front side), and therefore may be considered frontside interconnect layers. The metal layers 122 are disposed over a side 234 of the device region 121 opposite the side 230 (e.g., over a back side), and therefore may be considered backside interconnect layers.

Various metal layers 122, 123 may be used to interconnect the various inputs and outputs of the devices (e.g., logic devices) in the FEOL layer 252. In one example, each of the metal layers 122, 123 may include vias and lines/trenches. For example, the metal layers 122 include vias 228b (or via portions) and lines 228a (or trench portions). The lines 228a of a metal layer are configured for transferring signals and power along electrically conductive (e.g., metal) lines (also sometimes referred to as “trenches”) extending in the x-y plane (e.g., in the x or y directions), while the vias 228b of a metal layer are configured for transferring signals and power through electrically conductive vias extending in the z-direction, e.g., to any of the adjacent metal layers above or below. Accordingly, in one example, vias connect metal structures (e.g., metal lines or vias) from one metal layer to metal structures of an adjacent metal layer. While referred to as “metal” layers, various layers of the metal layers 122, 123 may include only certain patterns of conductive metals, e.g., copper (Cu), aluminum (Al), tungsten (W), or cobalt (Co), or metal alloys, or more generally, patterns of an electrically conductive material, formed in an insulating medium such as an interlayer dielectric (ILD) material 226. The dielectric material 226 may include any suitable ILD materials such as silicon oxide, carbon-doped silicon oxide, silicon carbide, silicon nitride, aluminum oxide, and/or silicon oxynitride. In some embodiments, the dielectric material 226 disposed between the interconnect structures in different ones of the interconnect layers and disposed in the device region 121 may have different compositions; in other embodiments, the composition of the dielectric material 226 between different interconnect layers and/or in the device region 121 may be the same. The example illustrated in FIG. 2 depicts three a certain number of metal layers 122, 123, however, fewer or more interconnect layers may be present. In some examples, the metal layers 122, 123 may also include devices (e.g., backend devices). Some dies may include more, fewer, and or different layers/regions than shown in FIG. 2. For example, some dies may have only a device region and frontside metal layers 122, but lack backside metal layers. Other dies may lack a device region (e.g., such as an interconnect or bridge die).

In the example illustrated in FIG. 2, the carrier wafer was not removed prior to dicing, and therefore the die 112 includes a portion of the carrier wafer 102 (referred to herein as a substrate 202 or structural support) and a bonding interface 118 between the substrate 202 and the device region 121 (e.g., between the frontside metal layers 122 and the substrate 202). The substrate 202 may have a thickness 220 in a range of about 10 to 700 micron, where the thickness 220 is a dimension of the substrate 202 in a plane substantially orthogonal to the device region 121 (e.g., along the z-axis as shown in FIG. 2). The bonding interface 118 may have a thickness 222 in a range of about 150 nanometers to 5 micron, or about 300 nanometers to 3 micron, where the thickness 222 is a dimension of the bonding interface 118 in a plane substantially orthogonal to the substrate 202 (e.g., along the z-axis as shown in FIG. 2).

As mentioned above, the dicing process may result in damage to the dies. For example, the dielectric material that is conventionally used as a bonding material prior to dicing, such as silicon oxide, may prevent heat and charge transfer, which may lead to thermal damage (e.g., from a laser dicing process) and/or a plasma charging effect (e.g., from a plasma dicing process), which in turn may lead to cracks and/or delamination at the bonding interface 118. In contrast, examples of improved bonding interfaces that may reduce damage from the dicing process are described herein.

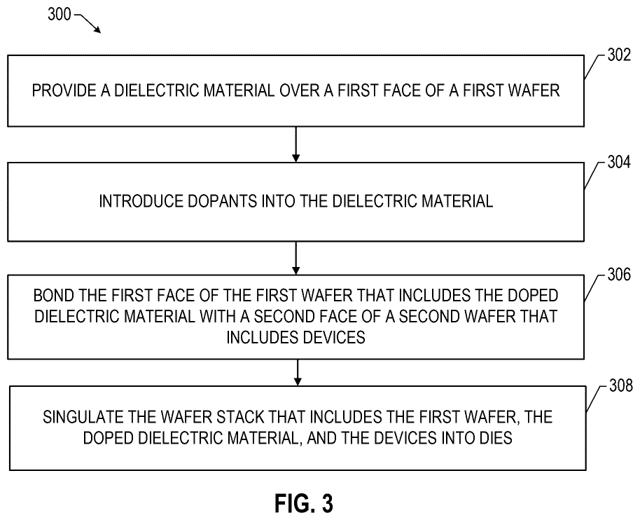

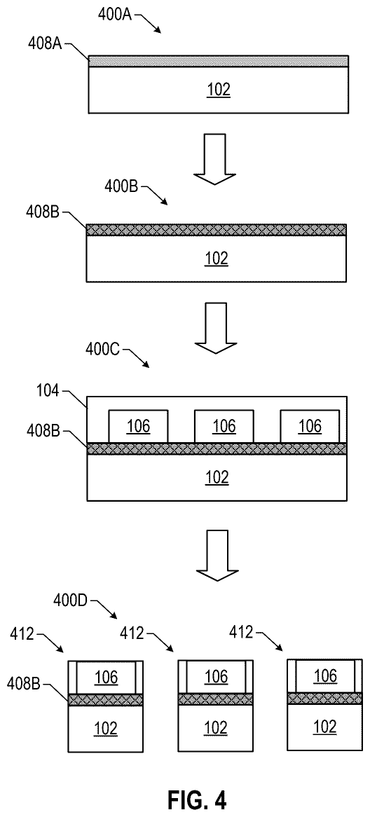

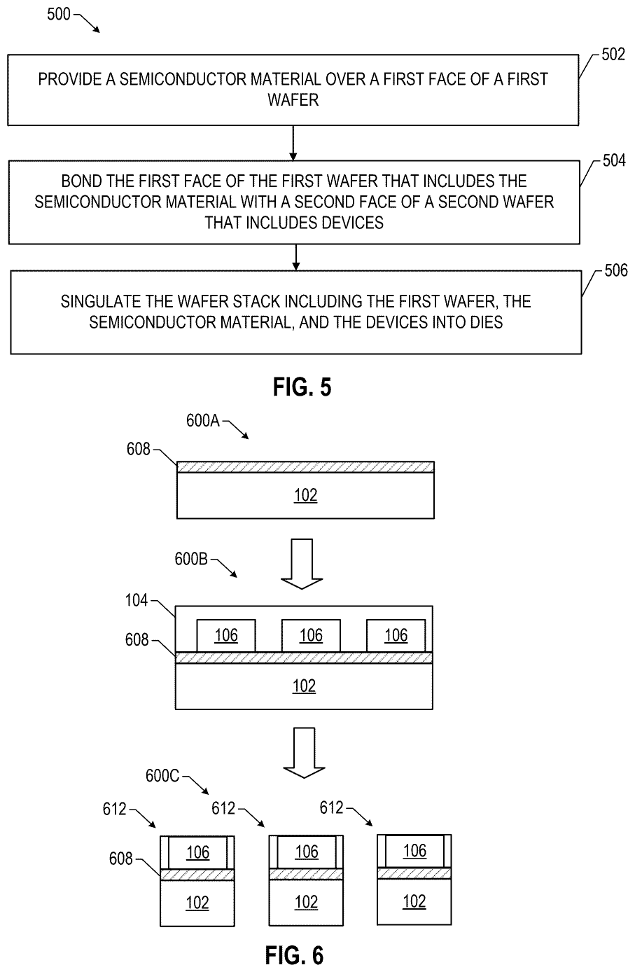

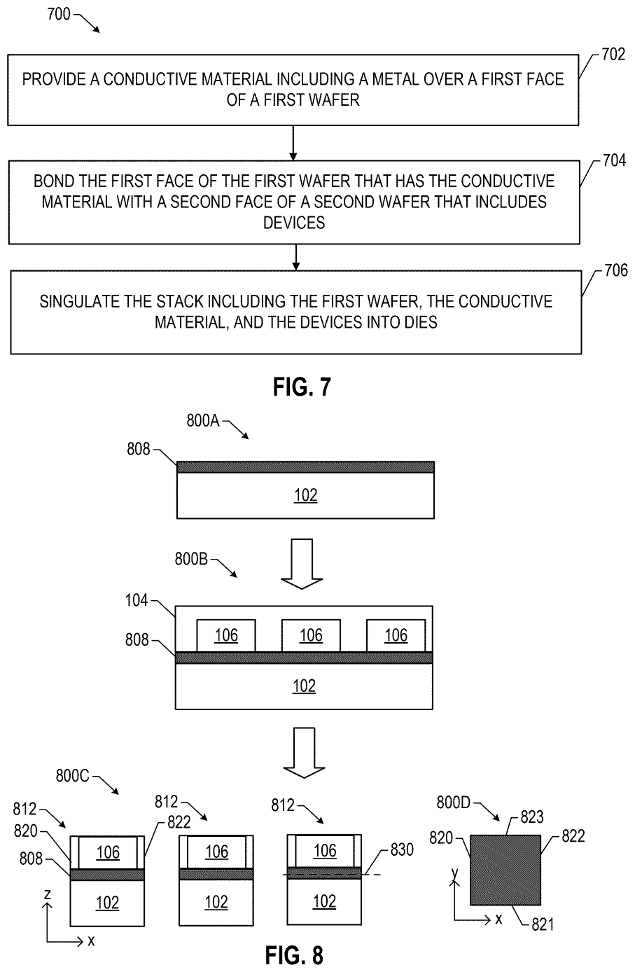

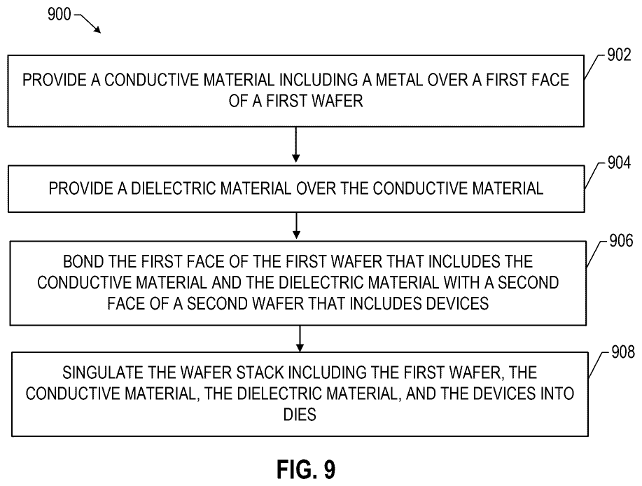

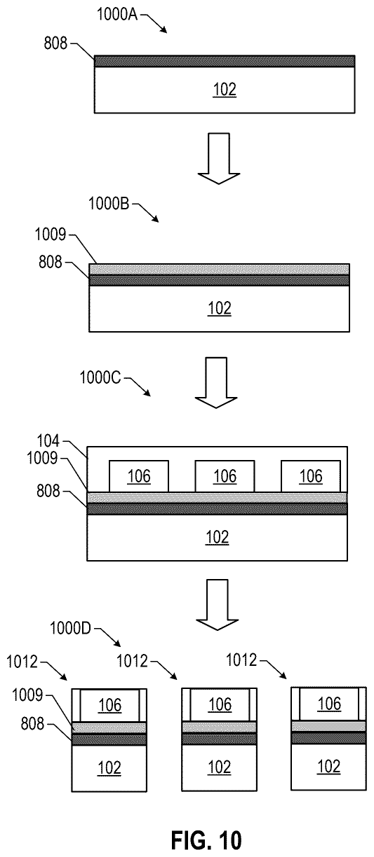

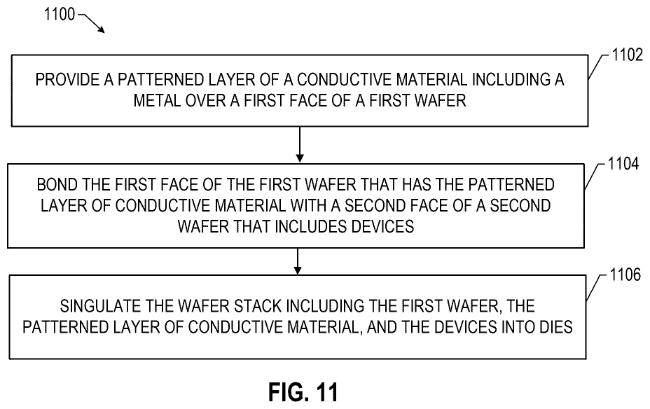

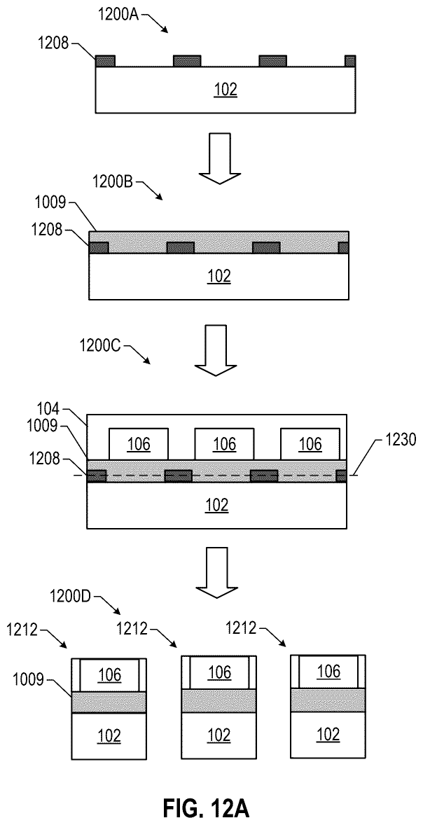

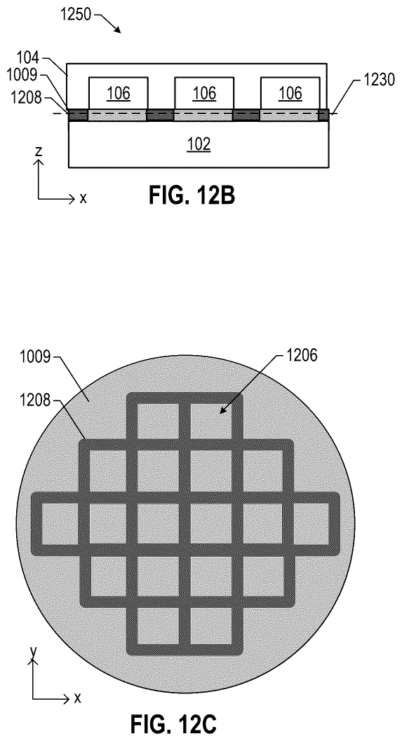

FIGS. 3, 5, 7, 9, and 11 are flow diagrams of example methods 300, 500, 700, 900, and 1100 for fabricating microelectronic components including a bonding interface between a die and carrier wafer that may reduce damage from the dicing process. The method 300 of FIG. 3 is an example method of fabricating a microelectronic component with a bonding interface that includes a doped dielectric material. FIG. 4 provides cross-sectional views along the x-z axis at various stages in the fabrication of an example microelectronic component according to the method 300 of FIG. 3. The method 500 of FIG. 5 is a method of fabricating a microelectronic component with a bonding interface that includes a semiconductor material. FIG. 6 provides cross-sectional views along the x-z axis at various stages in the fabrication of an example microelectronic component according to the method 500 of FIG. 5. The method 700 of FIG. 7 is a method of fabricating a microelectronic component with a bonding interface that includes a metal. FIG. 8 provides cross-sectional views along the x-z axis at various stages in the fabrication of an example microelectronic component according to the method 700 of FIG. 7. The method 900 of FIG. 9 is a method of fabricating a microelectronic component with a bonding interface that includes a metal and a dielectric material. FIG. 10 provides cross-sectional views along the x-z axis at various stages in the fabrication of an example microelectronic component according to the method 900 of FIG. 9. The method 1100 of FIG. 11 is a method of fabricating a microelectronic component with a bonding interface that includes a patterned metal and a dielectric material. FIGS. 12A-12C, 13A-13B, and 14A-14B provide cross-sectional views along the x-z axis at various stages in the fabrication of different examples of microelectronic components according to the method 1100 of FIG. 11.

Although the operations of the methods of FIGS. 3, 5, 7, 9, and 11 are illustrated once each and in a particular order, the operations may be performed in any suitable order and repeated as desired. For example, one or more operations may be performed in parallel to fabricate multiple microelectronic components including a bonding interface between a die and carrier wafer that may reduce damage from the dicing process substantially simultaneously. In another example, the operations may be performed in a different order to reflect the structure in which a bonding interface between a die and carrier wafer that may reduce damage from the dicing process will be implemented.

In addition, the example fabricating methods of FIGS. 3, 5, 7, 9, and 11 may include other operations not specifically shown in FIGS. 3, 5, 7, 9, and 11, such as various cleaning or planarization operations as known in the art. For example, in some embodiments, a support, as well as layers of various other materials subsequently deposited thereon, may be cleaned prior to, after, or during any of the processes of the methods described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the methods of FIGS. 3, 5, 7, 9, and 11 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

Turning to FIG. 3, the method 300 begins with a process 302 of providing a dielectric material over a first face of a first wafer. The view 400A of FIG. 4 shows an example result of the process 302. The view 400A depicts a wafer 102, which may be a carrier wafer, as discussed above. As can be seen in FIG. 4, a layer of a dielectric material 408A is provided over the wafer 102. The dielectric material 408A may be provided using any suitable technique, such as atomic layer deposition (ALD), chemical vapor deposition (CVD), plasma enhanced CVD (PECVD), or/and physical vapor deposition (PVD) processes such as sputter. The dielectric material 408A may be any suitable dielectric material to enable bonding between the wafer 102 and another wafer. In some examples, the dielectric material 408A may include silicon and oxygen (e.g., silicon oxide), silicon and nitrogen (e.g., silicon nitride), silicon, nitrogen, and carbon (e.g., silicon carbon nitride). In the example illustrated in FIG. 4, the layer of dielectric material 408A is a substantially uniform layer of the dielectric material 408A (e.g., the dielectric material 408A has substantially the same thickness across the wafer 102). In some examples, the thickness of the dielectric material 408A is in a range of about 150 nanometers to 10 micron, or in a range of about 200 nanometers to 5 micron, or in a range of about 300 nanometers to 3 micron, where the thickness is a dimension of the dielectric material 408A in a plane substantially orthogonal to the wafer 102.

The method 300 continues with a process 304 of introducing dopants (e.g., impurities) into the dielectric material. The view 400B of FIG. 4 shows an example result of the process 304. The view 400B depicts a layer of a doped dielectric material 408B, e.g., the layer of dielectric material 408A with dopants, over (e.g., on) the wafer 102. Introducing dopants into the dielectric material 408A may involve any suitable doping process, such as ion implantation, diffusion, or any other suitable doping technique. Examples of dopants that may be introduced into the dielectric material 408A include a metal, carbon, boron, and phosphorous. In some examples, the doped dielectric material 408B may have a dopant concentration between about 10¹⁴ cm⁻³ and about 10²¹ cm⁻³. In some examples, the presence of a dielectric material that includes an element as a dopant (e.g., a dielectric material doped with carbon) may be distinguished from a dielectric material that includes that element (e.g., a dielectric material that includes carbon, such as silicon carbon nitride) by the percentage of the dopant in the material. For example, silicon carbon nitride may have a stoichiometric ratio of about 1 to 1, whereas silicon nitride doped with carbon will have a significantly smaller concentration of carbon.

The method 300 continues with a process 306 of bonding the first face of the wafer that includes the doped dielectric material with a second face of a second wafer that includes devices. The view 400C of FIG. 4 shows an example result of the process 306. The view 400C depicts that a second wafer 104 has been bonded with the first wafer 102 using the doped dielectric material 408B as a bonding material. The wafers 102 and 104 may be bonded together using any suitable wafer-to-wafer bonding techniques, such as fusion bonding. The wafers may be bonded front-to-back, front-to-front, or back-to-back. In the example illustrated in FIG. 4, the front side of the wafer 104 is bonded with a front side of the wafer 102, exposing a back side of the wafer 104. Additional processing may be performed from the back side of the wafer 104, such as thinning or removal of the bulk substrate material of the wafer 104 from the back side and forming or otherwise providing metal layers from the back side of the wafer 104.

The method continues with a process 308 of singulating the wafer stack, which includes the first wafer, the doped dielectric material, and the devices from the second wafer. The view 400D of FIG. 4 shows an example result of the process 308. The view 400D depicts dies 412 (which may also be referred to as microelectronic components), which have been separated from one another using any suitable dicing process (e.g., a laser process, sawing process, a plasma process, or other suitable dicing process). In the example illustrated in FIG. 4, each of the dies 412 includes a portion of the wafer 102, devices from the wafer 102 (e.g., a die region or die 106 of the wafer 102), and the doped dielectric material 408B between the devices and the portion of the wafer 102.

Thus, FIG. 3 illustrates a method 300 for fabricating a microelectronic component with a bonding interface that includes a doped conductive material. Performing the method 300 may result in several features in the final microelectronic component that are characteristic of the use of the method 300. For example, one such feature is illustrated in the view 400D shown in FIG. 4, in which a die 412 includes a substrate (e.g., a portion of the carrier wafer 102), a device region over the substrate (e.g., a device region of the die 106), and a bonding interface between the substrate and the device region, where the bonding interface includes a layer of a dielectric material and one or more dopants.

As mentioned above, the dicing process may cause damage to the bonding interface between the wafer 102 and the wafer 104. According to some examples, using the doped dielectric material 408B as a bonding material may reduce or prevent damage at the bonding interface that may be caused by the die prep process. For example, the dopants in the dielectric material may increase the thermal conductivity of the dielectric material in the bonding in the bonding interface, which may prevent hot spots and damage during the die prep process. However, too high of a dopant concentration may jeopardize the structural and/or bonding properties of the dielectric material.

FIG. 5 is a flow diagram of another method 500 of fabricating microelectronic components including a bonding interface between a die and carrier wafer that includes a semiconductor material. The method 500 begins with a process 502 of providing a semiconductor material over a first face of a first wafer. The view 600A of FIG. 6 shows an example result of the process 502. The view 600A depicts a wafer 102 (e.g., a carrier wafer) and a layer of a semiconductor material 608 over the wafer 102. The semiconductor material 608 may be provided using any suitable technique, such as ALD, CVD, PECVD, or/and PVD processes. The semiconductor material 608 may be any suitable semiconductor material to enable bonding between the wafer 102 and another wafer. In some examples, the semiconductor material 608 may include silicon and carbon (e.g., silicon carbide), gallium and nitrogen (e.g., gallium nitride), and/or aluminum and nitrogen (e.g., aluminum nitride). In the example illustrated in FIG. 6, the layer of semiconductor material 608 is a substantially uniform layer of the semiconductor material 608 (e.g., the semiconductor material 608 has substantially the same thickness across the wafer 102). In some examples, the thickness of the semiconductor material 608 is in a range of about 150 nanometers to 10 micron, or in a range of about 200 nanometers to 5 micron, or in a range of about 300 nanometers to 3 micron, where the thickness is a dimension of the semiconductor material 608 in a plane substantially orthogonal to the wafer 102.

The method 500 continues with a process 504 of bonding the first face of the wafer that includes the semiconductor material with a second face of a second wafer that includes devices. The view 600B of FIG. 6 shows an example result of the process 504. The view 600B depicts that a second wafer 104 has been bonded with the first wafer 102 using the semiconductor material 608 as a bonding material. The wafers 102 and 104 may be bonded together using any suitable wafer-to-wafer bonding techniques, such as fusion bonding. The wafers may be bonded front-to-back, front-to-front, or back-to-back. In the example illustrated in FIG. 6, the front side of the wafer 104 is bonded with a front side of the wafer 102, exposing a back side of the wafer 104. Additional processing may be performed from the back side of the wafer 104, such as thinning or removal of the bulk substrate material of the wafer 104 from the back side and forming or otherwise providing metal layers from the back side of the wafer 104.

The method continues with a process 506 of singulating the wafer stack, which includes the first wafer, the semiconductor material, and the devices from the second wafer. The view 600C of FIG. 6 shows an example result of the process 506. The view 600C depicts dies, which have been separated from one another using any suitable dicing process (e.g., a laser process, sawing process, a plasma process, or other suitable dicing process). In the example illustrated in FIG. 6, each of the dies 612 includes a portion of the wafer 102, devices from the wafer 102 (e.g., a die region or die 106 of the wafer 102), and the semiconductor material 608 between the devices and the portion of the wafer 102.

Thus, FIG. 5 illustrates a method 500 for fabricating a microelectronic component with a bonding interface that includes a semiconductor material. Performing the method 500 may result in several features in the final microelectronic component that are characteristic of the use of the method 500. For example, one such feature is illustrated in the view 600C shown in FIG. 6, in which a die 612 includes a substrate (e.g., a portion of the carrier wafer 102), a device region over the substrate (e.g., a device region of the die 106), and a bonding interface between the substrate and the device region, where the bonding interface includes a semiconductor material. According to examples, replacing the dielectric bonding material with a semiconductor material may reduce defects at the bonding interface between bonded wafers. For example, the semiconductor material 608 may have a higher thermal conductivity and/or electrical conductivity than dielectric bonding materials, and may also absorb more laser light (e.g., from a dicing process) than dielectric bonding materials.

FIG. 7 is a flow diagram of another method 700 of fabricating microelectronic components including a bonding interface between a die and carrier wafer that includes a conductive material. The method 700 begins with a process 702 of providing a conductive material over a first face of a first wafer. The view 800A of FIG. 8 shows an example result of the process 702. The view 800A depicts a wafer 102 (e.g., a carrier wafer) and a layer of a conductive material 808 over the wafer 102. The conductive material 808 may be provided using any suitable technique, such as ALD, CVD, PECVD, or/and PVD processes. The conductive material 808 may be any suitable conductive material that includes one or more metals, and which may enable bonding between the wafer 102 and another wafer. In some examples, the conductive material 808 may include one or more of: aluminum, copper, and a solder material (e.g., a eutectic solder material). Examples of solder materials include: lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In the example illustrated in FIG. 8, the layer of conductive material 808 is a substantially uniform layer of the conductive material 808 (e.g., the conductive material 808 has substantially the same thickness across the wafer 102). In some examples, the layer of the conductive material 808 extends substantially across the entire bonding interface, e.g., the layer of the conductive material 808 may be a continuous sheet of metal. In some examples, the thickness of the semiconductor material 808 is in a range of about 150 nanometers to 10 micron, or in a range of about 200 nanometers to 5 micron, or in a range of about 300 nanometers to 3 micron, where the thickness is a dimension of the conductive material 808 in a plane substantially orthogonal to the wafer 102.

The method 700 continues with a process 704 of bonding the first face of the wafer that includes the conductive material with a second face of a second wafer that includes devices. The view 800B of FIG. 8 shows an example result of the process 704. The view 800B depicts that a second wafer 104 has been bonded with the first wafer 102 using the conductive material 808 as a bonding material. The wafers 102 and 104 may be bonded together using any suitable wafer-to-wafer bonding techniques, such as fusion bonding. The wafers may be bonded front-to-back, front-to-front, or back-to-back. In the example illustrated in FIG. 8, the front side of the wafer 104 is bonded with a front side of the wafer 102, exposing a back side of the wafer 104. Additional processing may be performed from the back side of the wafer 104, such as thinning or removal of the bulk substrate material of the wafer 104 from the back side and forming or otherwise providing metal layers from the back side of the wafer 104.

The method continues with a process 706 of singulating the wafer stack, which includes the first wafer, the conductive material, and the devices from the second wafer. The view 800C of FIG. 8 shows an example result of the process 706. The view 800C depicts dies, which have been separated from one another using any suitable dicing process (e.g., a laser process, sawing process, a plasma process, or other suitable dicing process). In the example illustrated in FIG. 8, each of the dies 812 includes a portion of the wafer 102, devices from the wafer 102 (e.g., a die region or die 106 of the wafer 102), and the conductive material 808 between the devices and the portion of the wafer 102. In some examples, the layer of the conductive material 808 is isolated from (e.g., electrically and physically isolated from) conductive interconnects (e.g., all conductive structures) of the interconnect layers of the die 106. For example, referring again to FIG. 2, the plurality of conductive interconnects 227 of the metal layers 122 may be isolated from the bonding interface 118 in an example where the bonding interface 118 includes a conductive material in order to avoid shorting the plurality of conductive interconnects 227 of the metal layers 122 together. In one such example, the face/side of the wafer 104 that is bonded with the wafer 102 may include a layer of an insulator material to insulate conductive interconnects from the conductive material 808 of the bonding interface.

Thus, FIG. 7 illustrates a method 700 for fabricating a microelectronic component with a bonding interface that includes a conductive material. Performing the method 700 may result in several features in the final microelectronic component that are characteristic of the use of the method 700. For example, one such feature is illustrated in the view 800C shown in FIG. 8, in which a die 812 includes a substrate (e.g., a portion of the carrier wafer 102), a device region over the substrate (e.g., a device region of the die 106), and a bonding interface between the substrate and the device region, where bonding interface includes a continuous portion of a conductive material including a metal, and the continuous portion extends in a plane 830 substantially parallel with the substrate between a first edge 820 of the die 812 and a second edge 822 of the die 812 opposite the first edge 820. As shown in the view 800D of FIG. 8, in some examples, the continuous portion may further extend in the 830 plane between a third edge 821 of the die 812 and a fourth edge 823 of the die 812 opposite the third edge 821. Thus, in some examples, the layer of conductive material 808 may extend across the entire bonding interface, and may have substantially the same footprint as the die.

According to examples, replacing the dielectric bonding material with a conductive material may reduce defects at the bonding interface between bonded wafers. For example, the conductive material 808 may have a higher thermal conductivity and electrical conductivity than dielectric bonding materials, and may also absorb more laser light (e.g., from a dicing process) than dielectric bonding materials.

In the example illustrated in FIG. 8, the layer of the conductive material 808 is shown as being a uniform layer across the entire bonding interface between the wafer 102 and the wafer 104. Similarly, in the post-dicing view 800C, the conductive material 808 is depicted as a continuous layer between the device region of the die 106 and the portion of the carrier wafer 102. For example, if the substrate (e.g., carrier wafer portion) has a first footprint (e.g., a two-dimensional area of the substrate) and the layer of the conductive material 808 has a second footprint, the first footprint is substantially the same as the second footprint. In some examples, the bonding interface may include both a layer of conductive material and a dielectric material (or a semiconductor material).

FIG. 9 is a flow diagram of another method 900 of fabricating microelectronic components including a bonding interface between a die and carrier wafer that includes a conductive material and a dielectric material. The method 900 is similar to the method 700 in that it begins with a process 902 of providing a conductive material over a first face of a first wafer. The view 1000A of FIG. 10 (which is the same as the view 800A of FIG. 8) shows an example result of the process 902.

The method 900 continues with a process 904 of providing a dielectric material over the conductive material. The view 1000B of FIG. 10 shows an example result of the process 904. The view 1000B depicts that a layer of a dielectric material 1009 is over (e.g., on) the conductive material 808 over the wafer 102. The dielectric material 1009 may be provided in accordance with any suitable technique, such as those discussed above, and may include any suitable dielectric material that may be used to facilitate wafer-to-wafer bonding. In some examples, the dielectric material 1009 may be a doped dielectric material, such as the doped dielectric material 408B discussed above. In other examples, a layer of a semiconductor material (such as the semiconductor material 608) may be provided over the conductive material 808. In one example, the layer of the conductive material 808 and the layer of the dielectric material 1009 may each have a thickness between a few hundred nanometers and a few micron. In some examples, the layers of the conductive material 808 and dielectric material 1009 may have thicknesses in a range of about 150 nanometers to 10 micron, or in a range of about 200 nanometers to 5 micron, or in a range of about 300 nanometers to 3 micron.

The method 900 continues with a process 906 of bonding the first face of the wafer that includes the conductive material and the dielectric material with a second face of a second wafer that includes devices. The view 1000C of FIG. 10 shows an example result of the process 906. The view 1000C depicts that a second wafer 104 has been bonded with the first wafer 102 using the conductive material 808 and the dielectric material 1009 as bonding materials. The wafers 102 and 104 may be bonded together using any suitable wafer-to-wafer bonding techniques, such as fusion bonding, in accordance to examples described herein.

The method 900 continues with a process 908 of singulating the wafer stack, which includes the first wafer, the conductive material, the dielectric material, and the devices from the second wafer. The view 1000D of FIG. 10 shows an example result of the process 908. The view 1000D depicts dies, which have been separated from one another using any suitable dicing process. In the example illustrated in FIG. 10, each of the dies 1012 includes a portion of the wafer 102, devices from the wafer 102 (e.g., a die region or die 106 of the wafer 102), and the conductive material 808 and the dielectric material 1009 between the devices and the portion of the wafer 102. In the example illustrated in the view 1000D FIG. 10, the layer of the conductive material 808 and the layer of the dielectric material 1009 have about the same footprint, e.g., they are continuous layers across substantially the entire bonding interface.

Thus, FIG. 9 illustrates a method 900 for fabricating a microelectronic component with a bonding interface that includes a conductive material and a dielectric material. Performing the method 900 may result in several features in the final microelectronic component that are characteristic of the use of the method 900. For example, one such feature is illustrated in the view 1000D shown in FIG. 10, in which a die 1012 includes a substrate (e.g., a portion of the carrier wafer 102), a device region over the substrate (e.g., a device region of the die 106), and a bonding interface between the substrate and the device region, where bonding interface includes a layer of the conductive material 808 and a layer of the dielectric material 1009. Another such feature is shown in FIG. 2, which shows that a die 112 including a metallization stack (e.g., metal layers 122) between the bonding interface 118 and the device region 121, where conductive interconnects are absent between the continuous portion of conductive material of the bonding interface 118 and the metallization stack. Similar to the example depicted in the view 800D of FIG. 8, the conductive material may extend across substantially the entire bonding interface. Similarly, the dielectric material 1009 may also extend across substantially the entire bonding interface between the conductive material 808 and the device region.

According to examples, using both the conductive material and a dielectric material may reduce defects at the bonding interface between bonded wafers due to increased thermal conductivity and electrical conductivity than dielectric bonding materials alone, and may also absorb more laser light (e.g., from a dicing process) than dielectric bonding materials.

Thus, FIGS. 7 and 9 are flow diagrams that illustrate example processes of fabricating microelectronic components in which a continuous conductive material is used as a bonding material. In other examples, a bonding interface may include a conductive material that is patterned.

For example, FIG. 11 is a flow diagram of another method 1100 of fabricating microelectronic components including a bonding interface between a die and carrier wafer that includes a patterned conductive material and a dielectric material. FIGS. 12A-12C, 13A-13B, and 14A-14B illustrate different examples of bonding interfaces that include a patterned layer of a conductive material. The method 1100 begins with a process 1102 of providing a patterned layer of a conductive material over a first face of a first wafer. The view 1200A of FIG. 12A shows one example result of the process 1102. The view 1200A depicts a patterned conductive material 1208 over a wafer 102. The patterned conductive material may be provided using an additive or subtractive process. For example, the conductive material may be deposited in accordance with any technique described herein, and then patterned. In another example, the conductive material may be deposited only in the desired regions.

In the example illustrated in the view 1200A, the patterned conductive material 1208 is provided in scribe regions (e.g., scribe regions of the carrier wafer and/or of another die to be bonded with the carrier wafer), but not in the device regions (e.g., not aligned with the dies 106). The method 1100 may continue with a process of providing a dielectric material over the patterned conductive material 1208. The view 1200B of FIG. 12A depicts a dielectric material 1009 over and between portions of the patterned conductive material 1208. Although FIG. 12A shows the dielectric material 1009 as being deposited after the patterned conductive material 1208, in other examples, the dielectric material 1009 may be deposited before the conductive material 1208.

The method 1100 continues with a process 1104 of bonding the first face of the wafer that includes the patterned conductive material with a second face of a second wafer that includes devices. The view 1200C of FIG. 12A shows an example result of the process 1104. The view 1200C depicts that a second wafer 104 has been bonded with the first wafer 102 using the patterned conductive material 1208 and the dielectric material 1009 as bonding materials. The wafers 102 and 104 may be bonded together using any suitable wafer-to-wafer bonding techniques, such as fusion bonding, in accordance to examples described herein. In the example illustrated in the view 1200C, a continuous portion of the dielectric material 1009 is present in the bonding interface on the side of the wafer 104. In other examples, the dielectric material 1009 may be present only between portions of the conductive material 1208 and not over the top of the conductive material 1208. For example, FIG. 12B is a cross-sectional view 1250 of an example wafer 102 with a patterned conductive material 1208 and dielectric material only between the portions of the conductive material 1208. In one example, the dielectric material 1009 over the portions of the patterned conductive material 1208 may have been removed (e.g., via a polish process), or the dielectric material 1009 may have only been deposited in between portions of the conductive material 1208. FIG. 12C is a cross-sectional view along a plane 1230 through the bonding interface, as shown in the view 1200C of FIG. 12A and the view 1250 of FIG. 12B. As can be seen in FIG. 12C, the conductive material 1208 is present along scribe lines, and absent in device regions 1206 (which may align with the dies 106). In the example illustrated in FIG. 12C, the dielectric material 1009 is present around and between portions of the conductive material 1208.

Referring again to FIG. 11, the method 1100 continues with a process 1106 of singulating the wafer stack, which includes the first wafer, the patterned conductive material, the dielectric material, and the devices from the second wafer. The view 1200D of FIG. 12A shows an example result of the process 1106. The view 1200D depicts dies, which have been separated from one another using any suitable dicing process. In the example illustrated in FIG. 12A, each of the dies 1012 includes a portion of the wafer 102, devices from the wafer 102 (e.g., a die region or die 106 of the wafer 102), and the dielectric material 1009 between the devices and the portion of the wafer 102. In the example illustrated in the view 1200D FIG. 12A, the patterned conductive material 1208 may be substantially absent from the dies 1212 due to the location of the conductive material 1208 in the scribe regions. Using a conductive material in scribe regions, such as shown in FIG. 12A, may have the benefit of improving thermal, electrical, and/or optical properties of the bonding interface without requiring a conductive material in bonding interface in areas below the device regions.

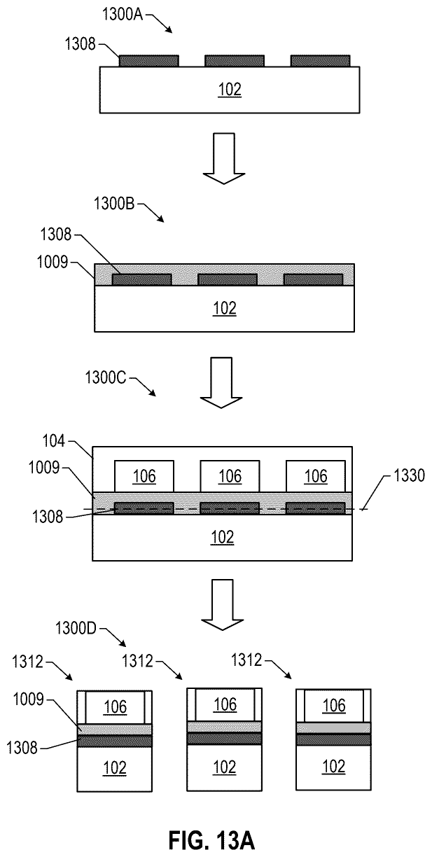

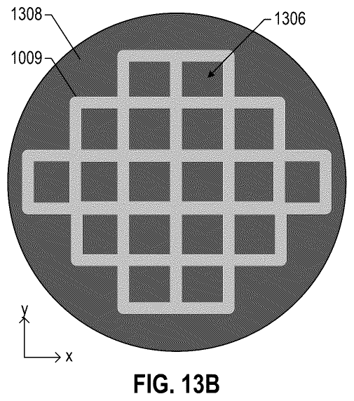

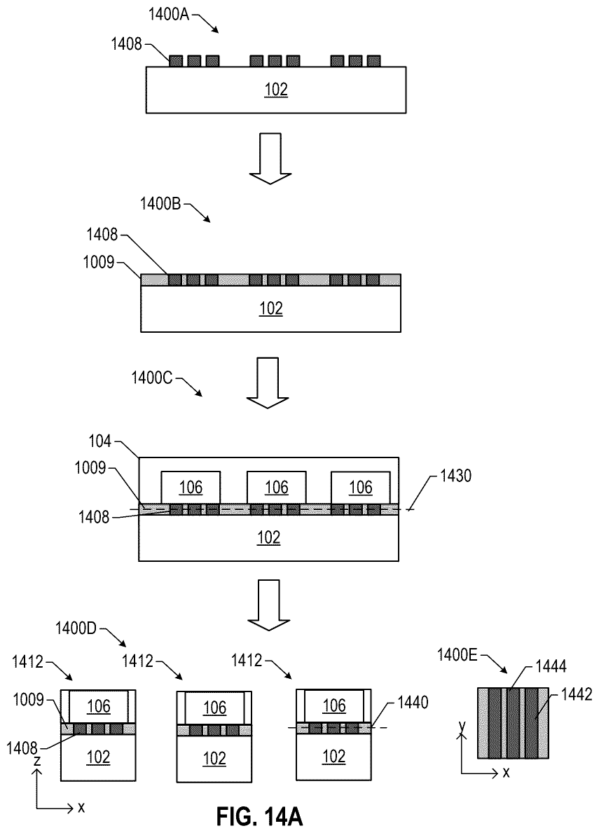

FIG. 13A shows cross-sectional views at various stages in the fabrication of microelectronic components in accordance with another example of the method 1100 of FIG. 11. A difference between FIG. 13A and FIG. 12A is that the patterned conductive material 1308 in FIG. 13A is provided in device regions instead of in scribe regions. For example, the view 1300A of FIG. 13A depicts the patterned conductive material 1308 over the wafer 102 as being substantially aligned with device regions of the wafer 104. The view 1300B of FIG. 13A depicts a dielectric material being provided around and over the patterned conductive material 1308. The view 1300C depicts a bonded wafer stack including the wafer 102, the wafer 104, and a bonding interface including the patterned conductive material 1308 and the dielectric material 1009. The view 1300D depicts the wafer stack after dicing, resulting in the dies 1312. In the example illustrated in the view 1300D of FIG. 13A, a die 1312 includes a continuous portion of the dielectric material 1009 between a continuous portion of the conductive material 1308 and the device region of the die 106.

FIG. 13B is a cross-sectional view along a plane 1330 through the bonding interface, as shown in the view 1300C of FIG. 13A. As can be seen in FIG. 13B, the conductive material 1308 is present in the die locations 1306 and absent along scribe lines. In the example illustrated in FIG. 13B, the dielectric material 1009 is in the scribe regions between portions of the conductive material 1308. In some examples, providing a bonding interface with a conductive material in areas such as below device regions may enable improved thermal conductivity in expected hot spots.

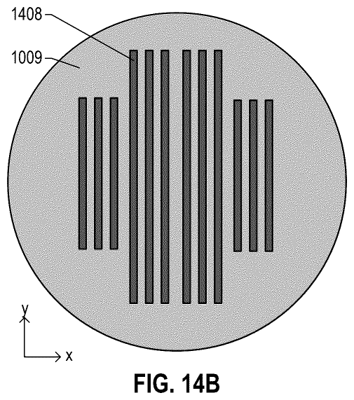

FIG. 14A shows cross-sectional views at various stages in the fabrication of microelectronic components in accordance with another example of the method 1100 of FIG. 11. A difference between FIG. 14A and FIGS. 12A and 13A is that the conductive material 1408 in FIG. 14A is that the pattern is not aligned with the dies or scribe regions. For example, the conductive material 1408 is patterned in lines. In one example, the conductive material 1408 may be patterned in such a way that the final dies include a patterned layer of the conductive material 1408. For example, the view 1400A of FIG. 14A depicts the patterned conductive material 1408 over the wafer 102. The view 1400B of FIG. 14B depicts a dielectric material being provided around the patterned conductive material 1408. The view 1400C depicts a bonded wafer stack including the wafer 102, the wafer 104, and a bonding interface including the patterned conductive material 1408 and the dielectric material 1009. The view 1400D depicts the wafer stack after dicing, resulting in the dies 1412. In the example illustrated in the view 1400D of FIG. 14A, a die 1412 includes the dielectric material 1009 between portions of the conductive material 1408. In other examples, the dielectric material 1009 may also be present over the portions of conductive material 1408.

FIG. 14B is a cross-sectional view along a plane 1430 through the bonding interface, as shown in the view 1400C of FIG. 14A. As can be seen in FIG. 14B, the conductive material 1408 is patterned in lines. In the example illustrated in FIG. 14B, the dielectric material 1009 is between portions of the conductive material 1408. In some examples, patterning the conductive material so it has some directionality (e.g., extends in lines in one direction, such as shown in FIG. 14B) may reduce or prevent warpage of the wafer stack.

Thus, FIG. 11 illustrates a method 1100 for fabricating a microelectronic component with a bonding interface that includes a patterned layer of a conductive material. Performing the method 1100 may result in several features in the final microelectronic component that are characteristic of the use of the method 1100. For example, one such feature is illustrated in the views 1400D and 1400E shown in FIG. 14A, in which a die 1412, where the layer of the conductive material 1408 is patterned. The view 1400E depicts a cross-section along a plane 1440 of a die 1412 (e.g., in the x-y plane). In the example illustrated in the view 1400E, the bonding interface includes a first portion 1442 of the conductive material 1408, a second portion 1444 of the conductive material 1408 coplanar with the first portion 1442, and a dielectric material 1009 coplanar with and between the first portion 1442 and the second portion 1444.

Accordingly, microelectronic components including a bonding interface between a die and carrier wafer described herein may reduce damage from the dicing process. For example, examples of bonding interfaces described herein may improve heat dissipation by increasing the thermal conductivity of the bonding layer over the carrier wafer. In some examples, higher electrical conductivity in the bonding layer can expedite charge dissipation during processing, which can reduce the risk of in-process charging damage (e.g., during a plasma etching process). Additionally, expedited charge dissipation may prevent accumulation of charge traps in the transistor, which may lead to improvements in transistor performance. In some examples, better laser absorption can improve the quality of the die prep process (e.g., dicing techniques employing lasers). The higher conductivity achieved with bonding interfaces described herein may reduce the risk of local hot spots that can lead to localized cracks, which can lead to an improvement in reliability. In some examples, by modulating stress in the film stack (e.g., by adjusting the thickness and/or pattern of a conductive layer), warpage can be controlled either in the wafer level or in die level to improve assembly yield and to reduce the thermo-mechanical reliability issues.

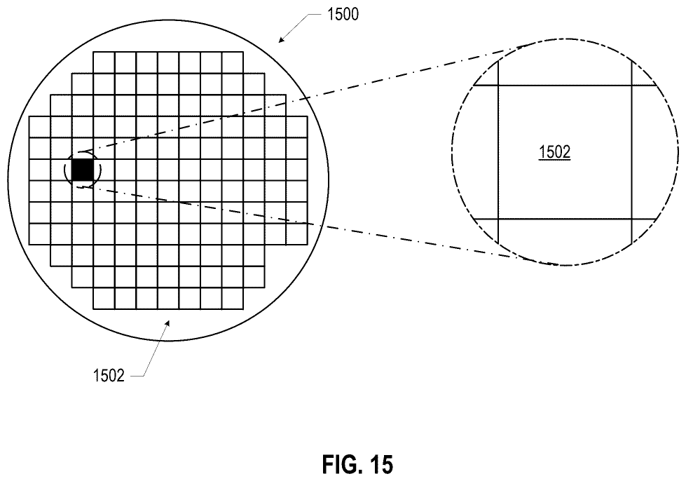

FIGS. 15-18 illustrate various examples of apparatuses that may include one or more of the microelectronic components including a bonding interface between a die and carrier wafer that may reduce damage from the dicing process as disclosed herein.

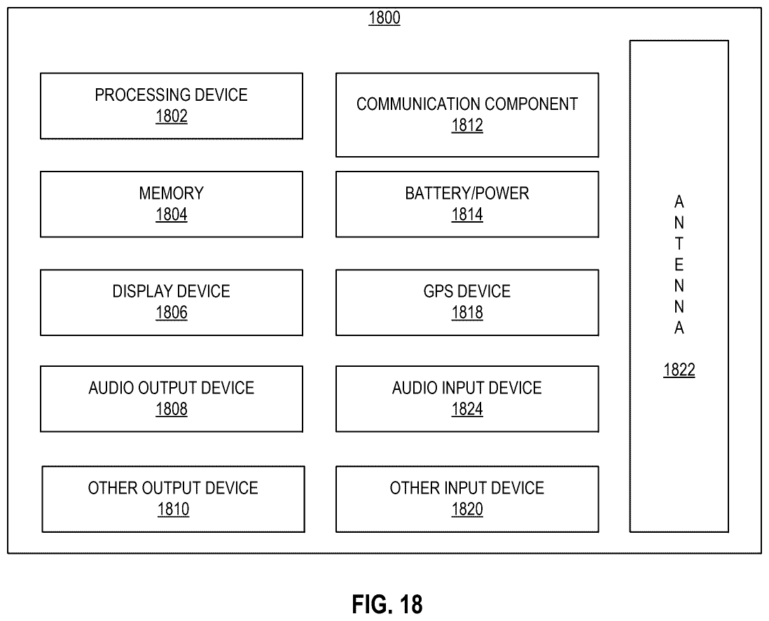

FIG. 15 is a top view of a wafer 1500 and dies 1502 that may include one or more IC structures in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 18) or other logic that is configured to store information in the memory devices or execute instructions stored in the memory array.

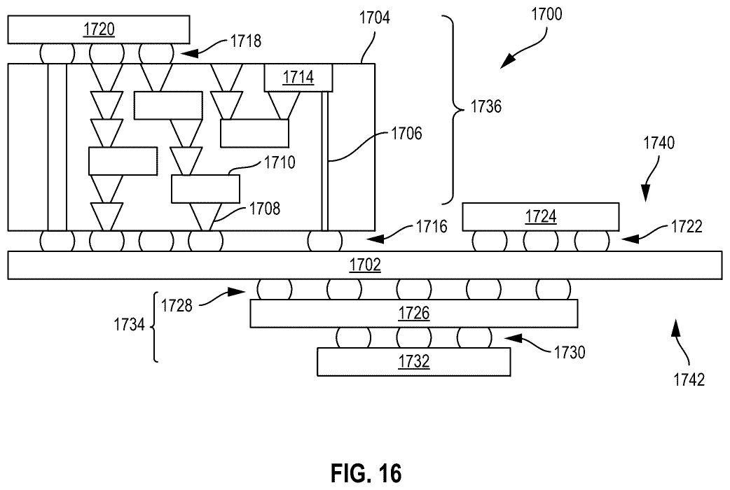

FIG. 16 is a side, cross-sectional view of an example IC package 1650 that may include an assembly including a bonding interface between a die and carrier wafer that may reduce damage from the dicing process in accordance with any of the embodiments disclosed herein. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 16 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 16 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

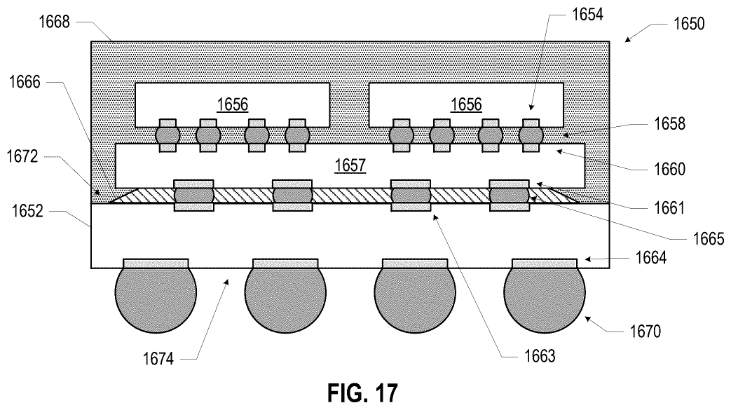

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 16 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 17.

The dies 1656 may take the form of any of the embodiments of the die 1502 discussed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 16 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fan-out (FO) package. Although two dies 1656 are illustrated in the IC package 1650 of FIG. 16, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 17 is a side, cross-sectional view of an IC device assembly 1700 that may include one or more IC packages or other electronic components (e.g., a die) including an assembly or one or more IC structures in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 16 (e.g., may include one or more IC structures in accordance with embodiments described herein).

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 17 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 17), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 17, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 15), an IC device, or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 17, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 17 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 18 is a block diagram of an example electrical device 1800 that may include an assembly including a bonding interface between a die and carrier wafer that may reduce damage from the dicing process in accordance with any of the embodiments disclosed herein. For example, any suitable ones of the components of the electrical device 1800 may include one or more of the IC device assemblies 1700, IC packages 1650, or dies 1502 disclosed herein. A number of components are illustrated in FIG. 18 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 18, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded DRAM (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP 2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include another output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.
Example 1 provides a microelectronic component, including a substrate (e.g., a portion of a carrier wafer); a device region over the substrate, where the device region includes one or more transistors; a plurality of interconnect layers (e.g., frontside metal layers) between the device region and the substrate; and a bonding interface between the substrate and the plurality of interconnect layers, where: the bonding interface includes a layer of a conductive material including a metal, and the layer of the conductive material is isolated from (e.g., electrically isolated from) conductive interconnects (e.g., all conductive structures) of the plurality of interconnect layers.
Example 2 provides the microelectronic component of example 1, where: the substrate has a first footprint, where the first footprint is a first two-dimensional area of the substrate, the layer of the conductive material has a second footprint, where the second footprint is a second two-dimensional area of the layer, and the first footprint is substantially the same as the second footprint (e.g., the metal layer may extend across substantially the entire bonding interface, e.g., may include a continuous sheet of metal).
Example 3 provides the microelectronic component of example 1, where: the layer of the conductive material is patterned.
Example 4 provides the microelectronic component of example 3, where: the bonding interface includes a first portion of the conductive material, a second portion of the conductive material coplanar with the first portion, and a dielectric material coplanar with and between the first portion and the second portion.
Example 5 provides the microelectronic component of any one of examples 1-4, where the layer is a first layer, and where: the bonding interface includes a layer of a dielectric material between the conductive material and the plurality of interconnect layers.
Example 6 provides the microelectronic component of example 5, where: the dielectric material is a doped dielectric material including one or more dopants.
Example 7 provides the microelectronic component of example 6, where the metal is a first metal, and where: the one or more dopants include one or more of: a second metal, carbon, boron, and phosphorous.
Example 8 provides the microelectronic component of example 4, where the layer is a first layer, and where: the bonding interface includes a layer of a semiconductor material between the conductive material and the plurality of interconnect layers.
Example 9 provides the microelectronic component of example 8, where: the semiconductor material includes one or more of: silicon and carbon, gallium and nitrogen, and aluminum and nitrogen.
Example 10 provides the microelectronic component of example 1, where: the bonding interface lacks a dielectric material.
Example 11 provides the microelectronic component of any one of examples 1-10, where: the metal includes one or more of: aluminum, copper, and a solder material.
Example 12 provides the microelectronic component of any one of examples 1-11, where: the substrate has a thickness in a range of about 10 to 700 micron.
Example 13 provides the microelectronic component of any one of examples 1-12, where: the plurality of interconnect layers include one or more conductive vias, where the one or more conductive vias taper in a direction from the bonding interface towards the device region (e.g., the interconnect layers are frontside metal layers).
Example 14 provides the microelectronic component of example 13, where the plurality of interconnect layers is a first plurality of interconnect layers, where the one or more conductive vias are one or more first conductive vias, the direction is a first direction, and where the microelectronic component further includes a second plurality of interconnect layers over the device region (e.g., backside metal layers), where: the second plurality of interconnect layers includes one or more second conductive vias, and the one or more second conductive vias taper in a second direction opposite the one or more first conductive vias (e.g., the backside metal layers have vias that have an opposite taper relative to the frontside metal layers).
Example 15 provides a microelectronic component, including a substrate (e.g., a portion of a carrier wafer); a device region over the substrate; and a bonding interface between the substrate and the device region, where: the bonding interface includes a continuous portion of a conductive material including a metal, and the continuous portion extends in a plane substantially parallel with the substrate between a first edge of the microelectronic component and a second edge of the microelectronic component opposite the first edge.
Example 16 provides the microelectronic component of example 15, further including a metallization stack between the bonding interface and the device region, where conductive interconnects are absent between the continuous portion and the metallization stack.
Example 17 provides the microelectronic component of any one of examples 15-16, where: the continuous portion further extends in the plane between a third edge of the microelectronic component and a fourth edge of the microelectronic component opposite the third edge.
Example 18 provides the microelectronic component of any one of examples 15-16, where the continuous portion is a first continuous portion, and where: the bonding interface further includes a second continuous portion of the conductive material, and a dielectric material between the first continuous portion and the second continuous portion.
Example 19 provides the microelectronic component of any one of examples 15-18, where: the bonding interface further includes a dielectric material between the continuous portion and the device region.
Example 20 provides the microelectronic component of example 19, where the metal is a first metal, and where: the dielectric material includes dopants, including one or more of a second metal, carbon, boron, and phosphorus.
Example 21 provides the microelectronic component of any one of examples 15-18, where: the bonding interface further includes a semiconductor material between the continuous portion and the device region.
Example 22 provides a method of fabricating a microelectronic component, where the method includes providing a layer of a conductive material including metal over a first side of a carrier wafer; bonding a second side of a device wafer with the first side of the carrier wafer, where the device wafer includes a plurality of devices; and dicing a wafer stack including the carrier wafer bonded with the device wafer into a plurality of dies, where a die of the plurality of dies includes one or more devices, a portion of the carrier wafer, and a bonding interface including the conductive material between the one or more devices and the portion.
Example 23 provides the method of example 22, where the layer is a first layer, and where the method further includes prior to bonding, providing a second layer of a dielectric material over the first layer of the conductive material.
Example 24 provides the method of example 23, further including doping the dielectric material prior to bonding.
Example 25 provides the method of any one of examples 22-24, where: providing the layer of the conductive material includes providing a patterned layer of the conductive material.
Example 26 provides the method of example 25, where: providing the patterned layer includes providing the conductive material in scribe regions of the carrier wafer.
Example 27 provides the method of example 25, where: providing the patterned layer includes providing the conductive material in regions corresponding to device regions of the device wafer.
Example 28 provides a microelectronic component, including a substrate (e.g., a portion of a carrier wafer); a device region over the substrate, where the device region includes one or more transistors; and a bonding interface between the substrate and the device region, where: the bonding interface includes a layer of a dielectric material and one or more dopants in the dielectric material.
Example 29 provides the microelectronic component of example 28, where: a concentration of dopants in the dielectric material is in a range of about 10¹⁴ cm⁻³ to 10²¹ cm⁻³.
Example 30 provides the microelectronic component of any one of examples 28-29, where: the dopants include one or more of: a metal, carbon, boron, and phosphorous.
Example 31 provides the microelectronic component of any one of examples 28-30, where: the dielectric material has a thickness in a range of about 200 nanometers to 5 microns.
Example 32 provides the microelectronic component of any one of examples 28-31, where the layer is a first layer, and where: the bonding interface includes a second layer of a metallic material between the first layer of the dielectric material and the substrate.
Example 33 provides a method of fabricating a microelectronic component, where the method includes providing a layer of a dielectric material over a first side of a carrier wafer; introducing one or more dopants into the dielectric material; bonding a second side of a device wafer with the first side of the carrier wafer, where the device wafer includes a plurality of devices; and dicing a wafer stack including the carrier wafer bonded with the device wafer into a plurality of dies, where a die of the plurality of dies includes one or more devices, a portion of the carrier wafer, and a bonding interface including the dielectric material and the one or more dopants between the one or more devices and the portion.
Example 34 provides the method of example 33, where: introducing the one or more dopants includes doping the dielectric material with one or more of a metal, carbon, boron, and phosphorous.
Example 35 provides the method of any one of examples 33-34, further including prior to providing the layer of the dielectric material, providing another layer of a conductive material including a metal.
Example 36 provides the method of example 35, where: providing the conductive material includes providing a patterned layer of the conductive material.
Example 37 provides a microelectronic component, including a substrate (e.g., a portion of a carrier wafer); a device region over the substrate, where the device region includes one or more transistors; and a bonding interface between the substrate and the device region, where the bonding interface includes a layer of a semiconductor material.
Example 38 provides the microelectronic component of example 37, where: the semiconductor material includes one or more of: silicon and carbon, gallium and nitrogen, and aluminum and nitrogen.
Example 39 provides the microelectronic component of any one of examples 37-38, where: the semiconductor material has a thickness in a range of about 200 nanometers to 5 microns.
Example 40 provides the microelectronic component of any one of examples 37-39, where the layer is a first layer, and where: the bonding interface includes a second layer of a metallic material between the first layer of the semiconductor material and the substrate.
Example 41 provides a method of fabricating a microelectronic component, where the method includes providing a layer of a semiconductor material over a first side of a carrier wafer; bonding a second side of a device wafer with the first side of the carrier wafer, where the device wafer includes a plurality of devices; and dicing a wafer stack including the carrier wafer bonded with the device wafer into a plurality of dies, where a die of the plurality of dies includes one or more devices, a portion of the carrier wafer, and a bonding interface including the semiconductor material between the one or more devices and the portion.
Example 42 provides the method of example 41, further including prior to providing the layer of the semiconductor material, providing another layer of a conductive material including a metal.
Example 43 provides a microelectronic component according to any one of examples 1-21, 28-32, and 37-40, where the microelectronic component includes or is a part of a central processing unit.
Example 44 provides a microelectronic component according to any one of examples 1-21, 28-32, 37-40, and 43, where the microelectronic component includes or is a part of a memory device.
Example 45 provides a microelectronic component according to any one of examples 1-21, 28-32, 37-40, and 43-44, where the microelectronic component includes or is a part of a logic circuit.
Example 46 provides a microelectronic component according to any one of examples 1-21, 28-32, 37-40, and 43-45, where the microelectronic component includes or is a part of input/output circuitry.
Example 47 provides a microelectronic component according to any one of examples 1-21, 28-32, 37-40, and 43-46, where the microelectronic component includes or is a part of a field programmable gate array transceiver.
Example 48 provides a microelectronic component according to any one of examples 1-21, 28-32, 37-40, and 43-47, where the microelectronic component includes or is a part of a field programmable gate array logic.
Example 49 provides a microelectronic component according to any one of examples 1-21, 28-32, 37-40, and 43-48, where the microelectronic component includes or is a part of a power delivery circuitry.
Example 50 provides an IC package that includes an IC die including a microelectronic component according to any one of examples 1-21, 28-32, 37-40, and 43-49; and a further IC component, coupled to the IC die.
Example 51 provides an IC package according to example 50 where the further IC component includes a package substrate.
Example 52 provides an IC package according to example 50, where the further IC component includes an interposer.
Example 53 provides an IC package according to example 50, where the further IC component includes a further IC die.
Example 54 provides a computing device that includes a carrier substrate and a microelectronic component coupled to the carrier substrate, where the microelectronic component is a microelectronic component according to any one of examples 1-21, 28-32, 37-40, and 43-49, or the microelectronic component is included in the IC package according to any one of examples 50-53.
Example 55 provides a computing device according to example 54, where the computing device is a wearable or handheld computing device.
Example 56 provides a computing device according to examples 54 or 55, where the computing device further includes one or more communication chips.
Example 57 provides a computing device according to any one of examples 54-56, where the computing device further includes an antenna.
Example 58 provides a computing device according to any one of examples 54-57, where the carrier substrate is a motherboard.
Example 59 provides the method according to any one of the preceding examples is a process of making a microelectronic component in accordance with any one of the preceding examples.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. A microelectronic component, comprising:
a substrate;
a device region over the substrate, wherein the device region comprises one or more transistors;
a plurality of interconnect layers between the device region and the substrate; and
a bonding interface between the substrate and the plurality of interconnect layers, wherein:
the bonding interface comprises a layer of a conductive material comprising a metal, and
the layer of the conductive material is isolated from conductive interconnects of the plurality of interconnect layers.

2. The microelectronic component of claim 1, wherein:
the substrate has a first footprint, wherein the first footprint is a first two-dimensional area of the substrate,
the layer of the conductive material has a second footprint, wherein the second footprint is a second two-dimensional area of the layer, and
the first footprint is substantially the same as the second footprint.

3. The microelectronic component of claim 1, wherein:
the layer of the conductive material is patterned.

4. The microelectronic component of claim 3, wherein:
the bonding interface comprises:
a first portion of the conductive material,
a second portion of the conductive material coplanar with the first portion, and
a dielectric material coplanar with and between the first portion and the second portion.

5. The microelectronic component of claim 1, wherein the layer is a first layer, and wherein:
the bonding interface comprises: a layer of a dielectric material between the conductive material and the plurality of interconnect layers.

6. The microelectronic component of claim 5, wherein:
the dielectric material is a doped dielectric material comprising one or more dopants.

7. The microelectronic component of claim 6, wherein the metal is a first metal, and wherein:
the one or more dopants comprise one or more of: a second metal, carbon, boron, and phosphorous.

8. The microelectronic component of claim 1, wherein the layer is a first layer, and wherein:
the bonding interface comprises: a layer of a semiconductor material between the conductive material and the plurality of interconnect layers.

9. The microelectronic component of claim 8, wherein:
the semiconductor material comprises one or more of: silicon and carbon, gallium and nitrogen, and aluminum and nitrogen.

10. The microelectronic component of claim 1, wherein:
the bonding interface lacks a dielectric material.

11. The microelectronic component of claim 1, wherein:
the metal comprises one or more of: aluminum, copper, and a solder material.

12. The microelectronic component of claim 1, wherein:
the substrate has a thickness in a range of about 10 to 700 micron.

13. The microelectronic component of claim 1, wherein:
the plurality of interconnect layers comprises one or more conductive vias, wherein the one or more conductive vias taper in a direction from the bonding interface towards the device region.

14. The microelectronic component of claim 13, wherein the plurality of interconnect layers is a first plurality of interconnect layers, wherein the one or more conductive vias are one or more first conductive vias, the direction is a first direction, and wherein the microelectronic component further comprises:
a second plurality of interconnect layers over the device region, wherein:
the second plurality of interconnect layers comprises one or more second conductive vias, and
the one or more second conductive vias taper in a second direction opposite the one or more first conductive vias.

15. A microelectronic component, comprising:
a substrate;
a device region over the substrate; and
a bonding interface between the substrate and the device region, wherein:
the bonding interface comprises a continuous portion of a conductive material comprising a metal, and
the continuous portion extends in a plane substantially parallel with the substrate between a first edge of the microelectronic component and a second edge of the microelectronic component opposite the first edge.

16. The microelectronic component of claim 15, further comprising:
a metallization stack between the bonding interface and the device region, wherein conductive interconnects are absent between the continuous portion and the metallization stack.

17. The microelectronic component of claim 15, wherein:
the continuous portion further extends in the plane between a third edge of the microelectronic component and a fourth edge of the microelectronic component opposite the third edge.

18. The microelectronic component of claim 15, wherein the continuous portion is a first continuous portion, and wherein:
the bonding interface further comprises:
a second continuous portion of the conductive material, and
a dielectric material between the first continuous portion and the second continuous portion.

19. A method of fabricating a microelectronic component, wherein the method comprises:
providing a layer of a conductive material comprising metal over a first side of a carrier wafer;
bonding a second side of a device wafer with the first side of the carrier wafer, wherein the device wafer comprises a plurality of devices; and
dicing a wafer stack comprising the carrier wafer bonded with the device wafer into a plurality of dies, wherein a die of the plurality of dies comprises one or more devices, a portion of the carrier wafer, and a bonding interface comprising the conductive material between the one or more devices and the portion of the carrier wafer.

20. The method of claim 19, wherein the layer is a first layer, and wherein the method further comprises:
prior to bonding, providing a second layer of a dielectric material over the first layer of the conductive material.
